(19) United States
(12) Patent Application Publication
(10) Pub. No.: US 2014/0049264 A1
(43) Pub. Date: Feb. 20, 2014

(54) PROGNOSTICS SYSTEM AND METHOD FOR FAULT DETECTION IN ELECTRICAL INSULATION

(71) Applicants: Meena Ganesh, Clifton Park, NY (US); Hunt Adams Sutherland, Saratoga Springs, NY (US); Bret Dwayne Worden, Erie, PA (US)

(72) Inventors: Meena Ganesh, Clifton Park, NY (US); Hunt Adams Sutherland, Saratoga Springs, NY (US); Bret Dwayne Worden, Erie, PA (US)

(21) Appl. No.: 14/008,901

(22) PCT Filed: Mar. 28, 2012
(86) PCT No.: PCT/US12/30781

§ 371 Date: Nov. 4, 2013

Related U.S. Application Data
(63) Continuation-in-part of application No. 13/077,789, filed on Mar. 31, 2011, now abandoned.
Application No. 13/077,789 is a continuation-in-part of application No. 13/077,805, filed on Mar. 31, 2011, now abandoned.

(51) Int. Cl. G01R 31/02

(52) U.S. Cl. CPC G01R 31/025
USPC 324/551

(57) ABSTRACT

A diagnostic/prognostics system for failure detection in an electrical insulation system is provided. The system includes at least two current transformers designed to detect high frequency component signals from the insulation system. The system also includes a data acquisition module coupled to the at least two current transformers, wherein the data acquisition module receives the high frequency component signals and analyzes the received high frequency component signals to identify one or more faulty components in the electrical insulation system.

### BACKGROUND

Embodiments relate generally to electrical insulation. Other embodiments relate to prognostic/diagnostic systems for electrical system insulation, e.g., for detecting faults in wires such as intermittent ground faults due to insulation degradation.

Locomotives and transit vehicles, as well as other large traction vehicles used for heavy haul applications (off-highway trucks), commonly use an electrical propulsion system that includes various high power electrical components, such as generators, rectifiers, converters, traction motors, dynamic braking grids, cooling blowers, and the like. These components may fail over time due to various reasons, one of them being electrical grounds that may be caused by insulation degradation. For example, locomotives may operate in environments subject to varying conditions, such as those causative of freezing and thawing, which can degrade an electrical insulation exposed to such varying conditions by causing cracks.

The propulsion system of a locomotive has many insulated windings, and excessive leakage current could develop over time due to various factors, such as aging, moisture, abrasions, dirt build-up and the like. This is especially true for the traction motors since moisture often gets into these components because of their location and exposure to relatively harsh environmental conditions. Failures due to excessive electrical leakage currents in an electrical system of locomotives are a leading cause of system shutdowns and locomotive mission failures.

Insulation failure in wires used in various applications, such as, but not limited to, locomotives and traction vehicles, is a critical safety concern since discharges from electrical wires may lead to on-board fires or other hazardous conditions. Insulation failure of wires has been primarily attributed to aging of the wires leading to cracks in the insulation. Furthermore, improper installation and handling may also lead to faults in insulation. Initial degradation in the insulation may start with microscopic cracks that result in small electrical discharges. The discharges may further carbonize the insulation leading to a full arc discharge. Hence maintenance of the wiring system is an important factor to the maintenance of the vehicles. However, wiring in typical vehicles may not be suitable for manual inspection for faults.

The need for manual inspection is generally avoided by deploying diagnostic sensors that may acquire electro-magnetic signals occurring due to electrical discharges in an electrical wire. However, existing diagnostic sensors are usually not very effective in detecting small electrical discharges. In order to increase the effectiveness, multiple diagnostic systems are deployed in a wiring system that can detect various magnitudes of electrical discharges. However, sensors in such diagnostic systems are generally associated with a magnetic core, which increases the weight of the diagnostic system and subsequently the weight of the electrical insulation system where such multiple diagnostic systems are deployed. Also, the high currents transmitted by the wiring can saturate the magnetic core, which renders the sensor ineffective.

Leakage current detectors have been used on many kinds of electrical equipment to protect the equipment from damage that could arise in the presence of a large electrical current and/or to protect personnel from injury, and there may be substantial industrial background on leakage current monitoring by techniques used in electrical utility or industrial applications. Ground faults may occur as a result of a fault in any of a number of different system components. In the context of a locomotive, such components by way of example can include the propulsion drive system, batteries, and auxiliary equipment. Within the propulsion drive system, ground faults can occur in one or several components, which include generator, rectifier, cabling, traction motor, dynamic brake resistor, and blower motor.

A generally known difficulty in dealing with ground conditions in a locomotive is that many of such conditions may be transitory in nature. Often when a ground fault condition occurs, the affected portion of the electrical system is deactivated, and the locomotive is scheduled for repairs. However, once the locomotive is shopped for repairs, the system may no longer exhibit abnormal grounds and the maintenance personnel cannot identify the source of the fault. This is often because the excessive discharge current is caused by moisture in the electrical components. By the time the locomotive is shopped, the moisture has dried out, thus eliminating the high discharge currents. The amount of moisture that is able to penetrate the insulation system and result in high leakage currents often depends in part on the condition of the insulation system. A healthy system experiences relatively small change in discharge current as a result of changing moisture conditions, whereas a system with degraded insulation may experience large changes in leakage current that is moisture dependent.

Therefore, there is a need for an improved prognostic/diagnostic system for electrical wires and insulation systems that addresses the aforementioned issues.

### BRIEF DESCRIPTION

In accordance with an embodiment of the invention, a diagnostic/prognostics system for failure detection in an electrical insulation system is provided. The system includes at least two current transformers designed to detect high frequency component signals from the insulation system. The system also includes a data acquisition module coupled to the at least two current transformers, wherein the data acquisition module receives the high frequency component signals and analyzes the received high frequency component signals to identify one or more faulty components in the electrical insulation system.

In accordance with another embodiment of the invention, a method for failure detection in an electrical insulation system is provided. The method includes detecting high frequency component signals from the insulation system via at least two current transformers. The method also includes receiving the high frequency component signals. The method further includes analyzing the received high frequency component signals based upon meggered data to identify one or more faulty components in the electrical insulation system.

In accordance with another embodiment of the invention, a method for setting up a prognostics/diagnostics system for failure detection in an electrical insulation system is provided. The method includes electrically coupling at least two current transformers with the electrical insulation system, the current transformers designed to detect high frequency component signals from the insulation system. The method also includes coupling a data acquisition module to the at least two current transformers, the data acquisition module configured to receive and analyze the high frequency component signals based upon meggered data to identify one or more faulty components in the electrical insulation system.

In accordance with another embodiment of the invention, a passive system for insulation failure in an electrical system is provided. The system includes at least two current transformers that are clamped and are passively listening for fault signals when a megger test is being performed. The system also includes a data acquisition module comprising a plurality of software models continuously analyzing and producing a defect report or warning in real time when a fault s is detected.

In accordance with an embodiment of the invention, a diagnostic/prognostics system for intermittent ground fault detection in an electrical insulation system is provided. The system includes at least two current transformers designed to detect high frequency component signals, wherein at least one of the two current transformers is clamped to a ground detection module and the other is clamped to at least one electrically insulated component (of the electrical insulation system). The system also includes a data acquisition module coupled to the at least two current transformers, wherein the data acquisition module receives the high frequency component signals and analyzes the received high frequency component signals to detect leakage current and detect/predict an intermittent ground fault in the electrical insulation system.

In accordance with another embodiment of the invention, a method for intermittent ground fault detection in an electrical insulation system is provided. The method includes detecting high frequency component signals via at least two current transformers, wherein at least one of the two current transformers is electrically coupled to a ground detection module and the other is connected to at least one electrically insulated component. The method also includes receiving the high frequency component signals and analyzing the received high frequency component signals to detect a discharge event and predict an intermittent ground fault in the electrical insulation system.

In accordance with another embodiment of the invention, a method for setting up a prognostics/diagnostics system for intermittent ground fault detection in an electrical insulation system is provided. The method includes electrically coupling one of the at least two current transformers to a ground detection module and the other current transformer to at least one electrically insulated component, the current transformers designed to detect high frequency component signals from the insulation system. The method also includes coupling a data acquisition module to the at least two current transformers, the data acquisition module configured to receive and analyze the high frequency component signals to identify one or more faulty components in the electrical insulation system.

In accordance with yet another embodiment of the invention, a passive system for intermittent ground fault detection in an electrical insulation system is provided. The passive system includes at least two current transformers clamped and designed to passively sense one or more fault signals. The system also includes a data acquisition module comprising a plurality of software models that continuously analyze and produce a defect report or warning in real time when a fault signal is detected.

### DRAWINGS

These and other features, aspects, and advantages of the present invention will become better understood when the following detailed description is read with reference to the accompanying drawings in which like characters represent like parts throughout the drawings, wherein:

FIG. 1 is a schematic block diagram representation of a high level prognostics/diagnostics system for any electrical insulation system in accordance with an embodiment of the invention.

FIG. 2 is a block diagram representation of the flow of data in the prognostics/diagnostics system in FIG. 1.

FIG. 3 is a schematic representation of the prognostics/diagnostics system 10 (FIG. 1) employed in a traction motor insulation system wherein meggering is already being performed.

FIG. 4 is a graphical illustration of experimental measurements obtained from the prognostics/diagnostics system described in FIG. 3.

FIG. 5 is a graphical representation of a typical fast fourier transform (FFT) being performed on a typical acquired signal in FIG. 4.

FIG. 6 is graphical representation of the highest frequency obtained from the FFT analysis in FIG. 5 on the data for the ‘good’ motors and the ‘bad’ motors.

FIG. 7 is a graphical representation of the second highest frequency obtained from the FFT analysis on the data for the ‘good’ motors and the ‘bad’ motors.

FIG. 8 is an exemplary embodiment of the traction motors employed with a prognostics/diagnostics system in a locomotive propulsion system to determine intermittent ground faults in accordance with an embodiment of the invention.

FIG. 9 is a graphical representation of experiments performed via the prognostics/diagnostics system in FIG. 8.

FIG. 10 a flow chart representing steps in an exemplary method for failure detection in an electrical insulation system in accordance with an embodiment of the invention.

FIG. 11 is a flow chart representing steps in an exemplary method for setting up a prognostics/diagnostics system in an electrical insulation system in accordance with another embodiment of the invention.

FIG. 12 is a flow chart representing steps in an exemplary method for intermittent ground fault detection in an electrical insulation system in accordance with another embodiment of the invention.

FIG. 13 is a flow chart representing steps in an exemplary method for setting up a prognostics/diagnostics system for intermittent ground fault detection in an electrical insulation system.

### DETAILED DESCRIPTION

As discussed in detail below, embodiments of the invention include a prognostic system and method for wire insulation. The system and method enable accurate prediction of a failure in insulation of components such as, but not limited to, armature or field coils in traction motors. The technique includes acquiring high frequency component signals from the armature or field coils and analyzing the signals to determine a defective field coil/s based on modeling and signal analysis techniques. Although the description of figures below refers to a traction motor system, it should be understood by one skilled in the art that the technique is applicable to other electrical systems.

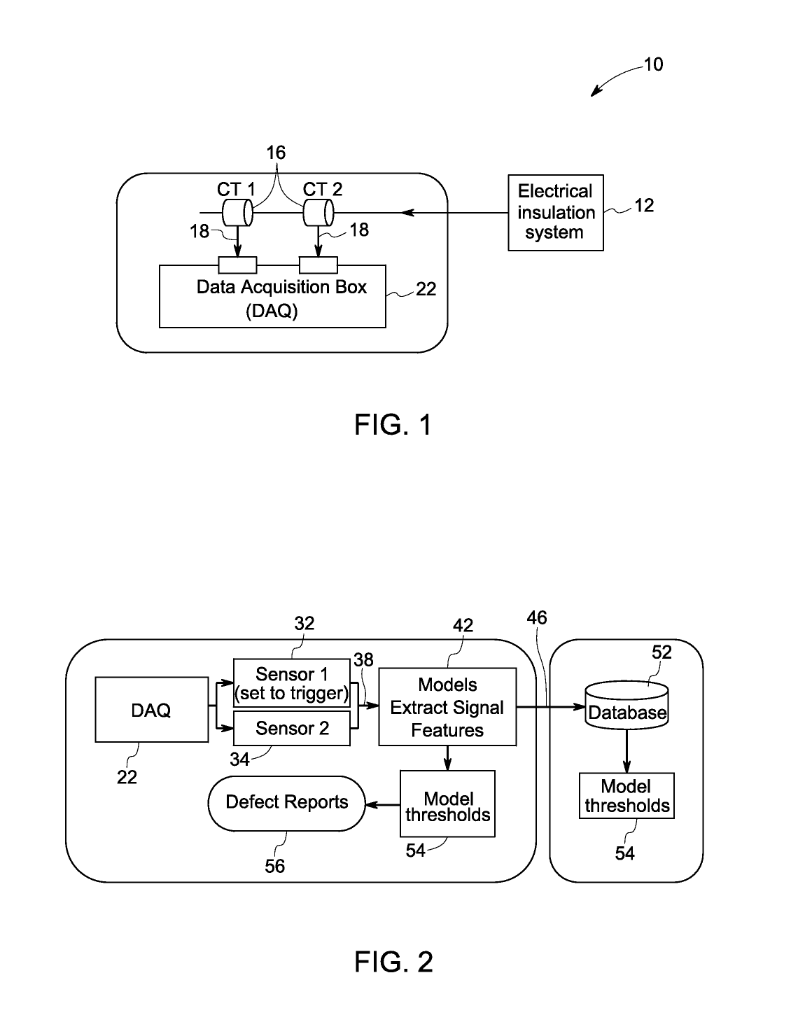

FIG. 1 is a schematic block diagram representation of a high level prognostics/diagnostics system 10 for any electrical insulation system 12. The system 10 includes two high frequency current transformers (HFCT) 16 that are coupled to the electrical insulation system 12 to detect high frequency component signals 18 generated from the insulation system 12. The HFCTs have a high bandwidth from about 10 Khz to about 200 Mhz. The acquired signals 18 are further fed into a data acquisition (DAQ) module 22. The DAQ module 22 includes software models that perform desired analysis of the signals 18 to identify defective insulations within the electrical insulation system 12. It should be noted that although two HFCTs 16 have been illustrated herein, more number of HFCTs gives a better sensitivity in detecting the defect.

FIG. 2 is a block diagram representation of the flow of data during the acquisition of data by the HFCTs 32 and 34 from the electrical insulation system 12 (FIG. 1). Typically, the data acquisition module 22 (FIG. 1) acquires data via the HFCTs 32, 34 at a sampling frequency of say, for example, about 500 MHz, with a sampling size of about 2500. HFCT 32 is set to trigger based upon a threshold value of the signal, and upon occurrence of a trigger, starts collecting data. Similarly, HFCT 34 simultaneously starts collecting data only upon occurrence of trigger of HFCT 32. The acquired signals 38 are fed into software models 42 that extract desired signal features 46 and are fed into a database 52. The signal features 46 are compared with model threshold values 54 and a defect is output in an event that the signal features 46 are greater than the threshold values 54. Accordingly, defect reports 56 are generated.

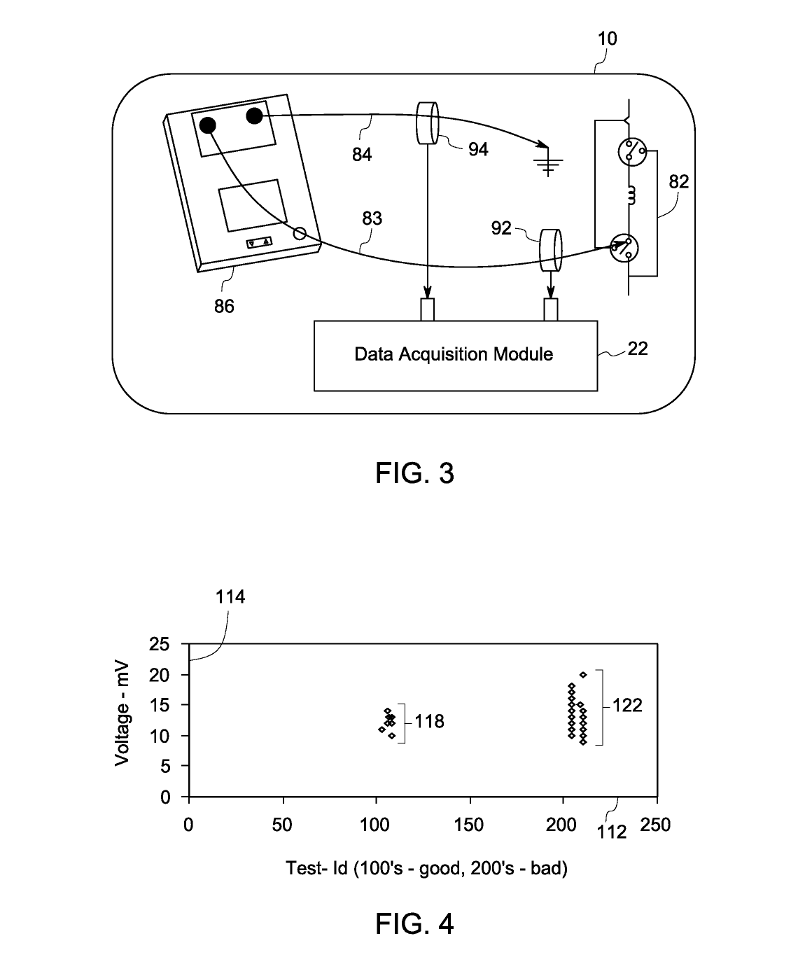

FIG. 3 is a schematic representation of the prognostics/diagnostics system 10 (FIG. 1) employed in a traction motor insulation system wherein meggering is already being performed. (“Meggering” or “megger test” may include measuring resistance using a relatively very high voltage, such as 300-1000 volts or higher, for checking for shorts to ground or otherwise.) Previously, with the meggering process alone, it would be possible to detect a faulty motor system. However, the detecting sensitivity is lower than that provided by the technique in this invention. Megger readings depend on environmental factors, like humidity. Accordingly, this technique enables in identifying the desired component. As illustrated herein, one lead 83 is connected from a traction motor field 82 to ohmmeter 86, while the other lead 84 is connected from the ohmmeter 86 to locomotive carbody ground. Additionally, HFCTs 92 and 94 are also connected to the electrical cables 84. The HFCTs 92 and 94 acquire data upon triggering of HFCT 92, and is further transmitted to the data acquisition module 98 for signal processing. Details of the signal analysis are described below.

FIG. 4 is a graphical illustration of experimental measurements obtained from the system described in FIG. 3. X-axis 112 represents an identification serial number for a set of traction motors tested. The serial numbers in the 100s were classified as ‘good’ or ‘non-faulty’ and the ones in the 200s were classified as ‘bad’ or ‘faulty’ purely based on the meggering data. Y-axis 114 represents maximum peak to peak (p-p) amplitude of the acquired signals in mV, after performing FFT as in FIG. 4. As illustrated herein, the ‘good’ set of motors had a maximum p-p amplitude of less than about 15 mV, as represented by reference numeral 118, and accordingly, the ‘bad’ set of motors (in the 200s) 122 were considered the ones having a maximum p-p amplitude of greater than 15 mV. This represents a first stage in the algorithm for detecting faulty motors.

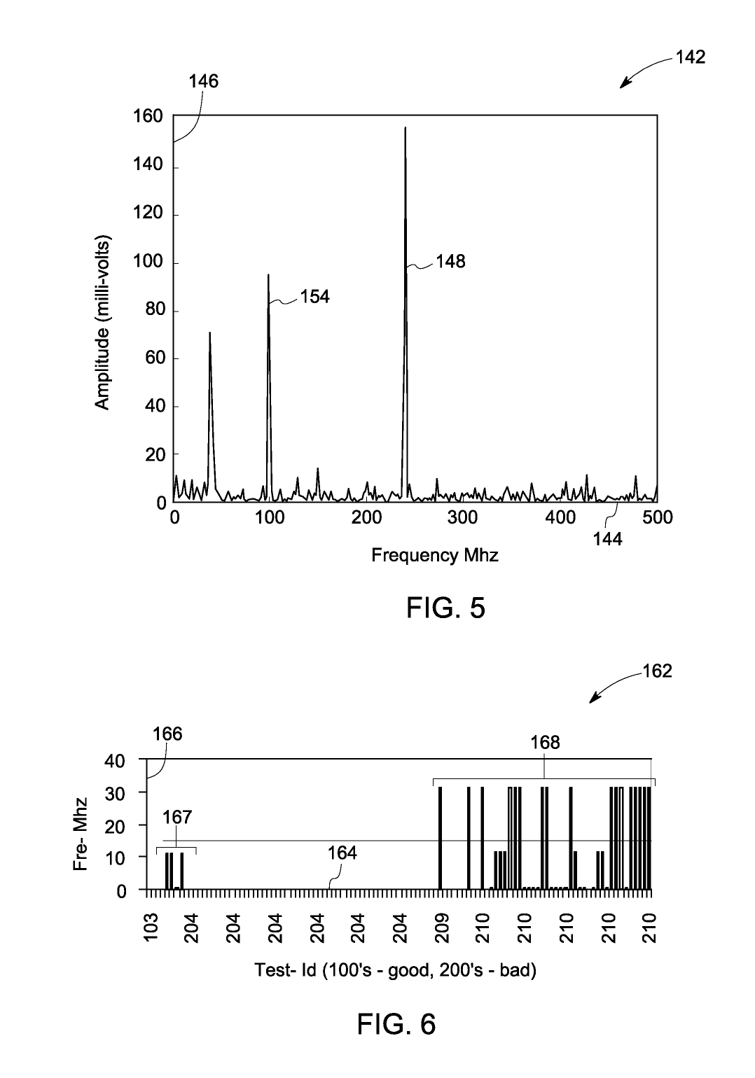

FIG. 5 is a graphical illustration 142 of a typical fast fourier transform (FFT) being performed on a typical acquired signal. X-axis 144 represents frequency in MHz, while Y-axis 146 represents amplitude in mV. As illustrated herein, the highest frequency signal in the frequency spectrum is classified based upon the amplitude of the respective signal. For example, the highest frequency ‘TopFreq1’ represented by reference numeral 148 has a highest amplitude of about 150 mV, while the second highest frequency signal ‘TopFreq2’ 154 corresponds to a second highest amplitude of 100 mV. Accordingly, the FFT analysis was performed on the measurements obtained in FIG. 3.

FIG. 6 is a graphical illustration 162 of the highest frequency obtained from the FFT analysis on the data for the ‘good’ motors and the ‘bad’ motors. X-axis 164 represents the identified serial numbers and Y-axis 166 represents frequency in MHz. As illustrated herein, the motors with serial numbers in the 100s (‘good’ motors) had a highest frequency of less than 15 MHz, and the motors with serial numbers in the 200s (‘bad’ motors) had in majority a frequency of greater than 15 MHz.

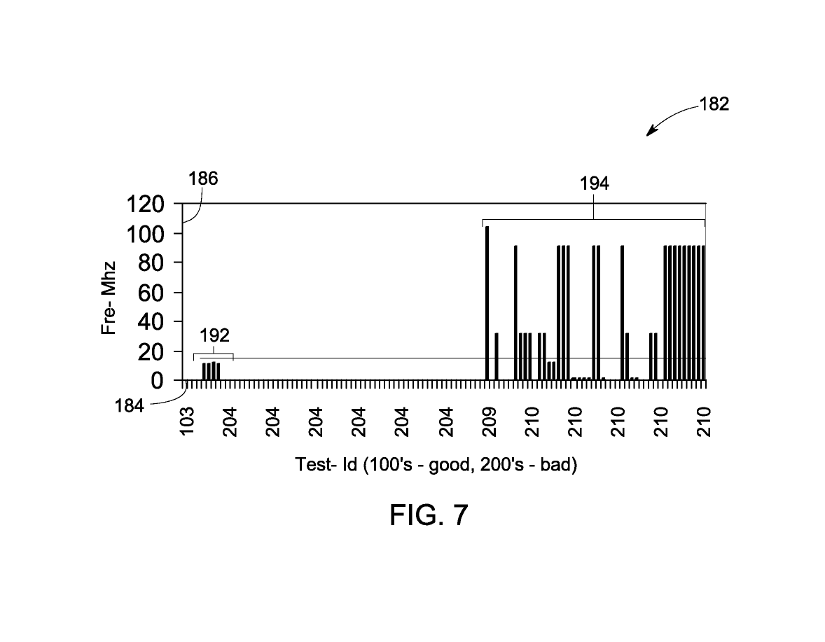

Similarly, FIG. 7 is a graphical illustration 182 of the second highest frequency obtained from the FFT analysis on the data for the ‘good’ motors and the ‘bad’ motors. X-axis 184 represents the identified serial numbers and Y-axis 186 represents frequency in MHz. Again, as illustrated herein, the motors with serial numbers in the 100s (‘good’ motors) had a highest frequency of less than 15 MHz, and the motors with serial numbers in the 200s (‘bad’ motors) had in majority a frequency of greater than 15 MHz.

Analysis of FIGS. 6 and 7 constitute a second stage of the algorithm to identify the faulty motors. Thus, based on the first stage analysis in FIG. 4 and the second stage analysis in FIG. 6, it may be concluded that the data set that indicates a spectral content of 15 MHz or higher and a maximum amplitude (p-p) of greater than 15 mV may be considered faulty and accordingly, diagnostic alerts may be transmitted.

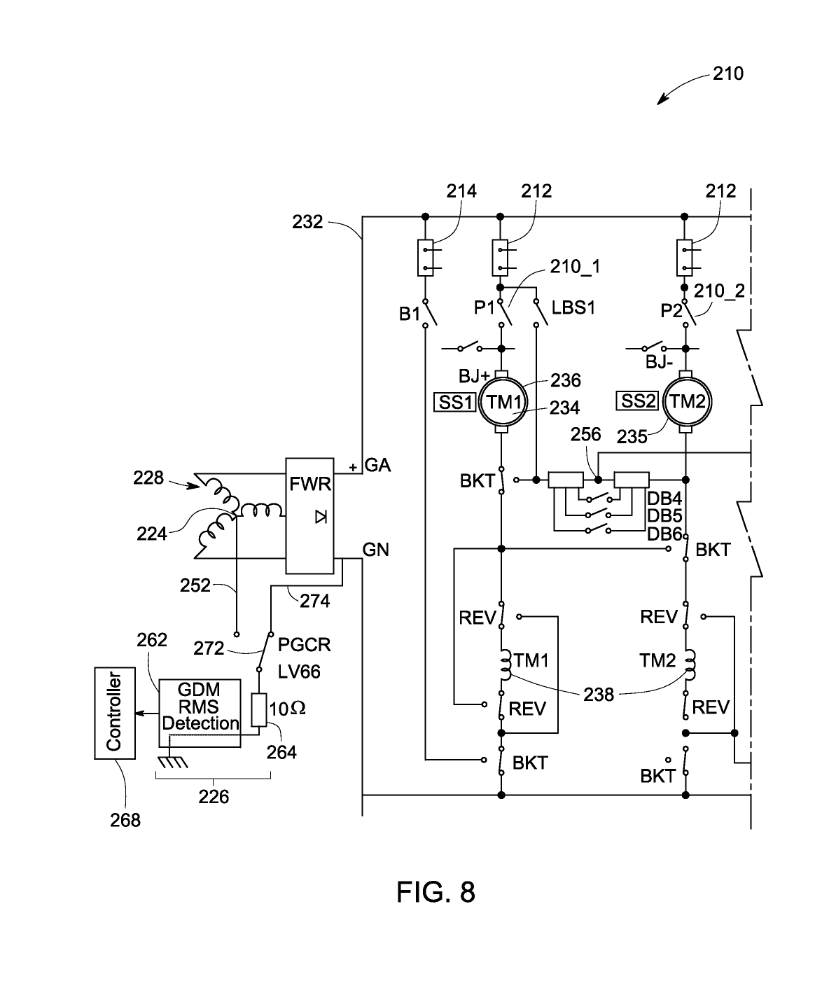

FIG. 8 is an exemplary embodiment of the traction motors employed in a locomotive propulsion system 210 to determine intermittent ground faults. Specifically, FIG. 8 is a schematic circuit diagram of a locomotive electrical system that includes HFCTs 212, 214 and, for purposes of example, comprises a propulsion system 224, such as may be configured for a typical DC (direct current) drive locomotive. In the illustrated embodiment, the HFCT 212 is electrically coupled to a faulty traction motor 234, while HFCT 214 is electrically connected to the ground detection module 226. Propulsion system 210 comprises a three-phase electromotive machine 228 (which may comprise a motor or generator, for example, and in the embodiment of FIG. 1 comprises a wye-connected generator 228 driven by a prime mover, such as a diesel engine (not shown). Tractive effort may be controlled by varying the excitation current, hence the output voltage, of machine 228. The AC (alternating current) voltage from generator 228 is then rectified by a rectifier 232 to produce DC voltage. Traction motors 234, 235 are usually series field DC traction motors each with an armature 236 and a field winding 238. There are typically four or six traction motors in a locomotive propulsion drive system 210, depending on the application, connected in parallel to a DC bus 242 across the rectified DC source.

The propulsion system further includes braking grids 246, made up of resistors as may be used during dynamic braking of the locomotive for dissipating electrical energy into thermal energy. One or more blower motors 248 are also connected to the DC bus 242. The blower motors may have multiple speeds that provide adjustable cooling air circulation to the braking grids 246 and traction motors 234. Although the description of monitoring intermittent ground faults contained herein is described in the context of a propulsion system for a typical DC drive locomotive, it is contemplated, and one skilled in the art will readily understand, that the techniques described below are also applicable to AC drive locomotive systems, as the invention is not limited to any particular type of electrical propulsion system. It is further contemplated that aspects of the present invention are applicable not just to locomotives but to any type of large, traction vehicle equipped with an electrical propulsion system, such as transit vehicles, and off-highway vehicles.

FIG. 8 also illustrates a first ground connection 252 for electrical propulsion system 210. This first ground connection forms a grounding path (e.g., from a neutral node 224 in generator 228 to the locomotive frame (e.g., ground)) that may be used by the electrical propulsion system during normal operation for electrical grounding purposes, e.g., to pass leakage current. This first ground connection may be selected to increase detectability or visibility of an incipient ground fault in the propulsion system. For example, in the case where the first ground connection is a neutral node connection, then such node provides appropriate electrical visibility to the entire system with the understanding that one potential blind spot could occur in the generator at a point electrically proximate to (or at) the neutral point 224. Thus, a neutral node connection may be selected as the ground connection during normal operation (e.g., no ground fault suspected). In another embodiment, potential blind spots may occur at or near braking grids 246, specifically, points 256.

In one exemplary embodiment, discharge current caused by ionization events or partial discharge events may be monitored by a current monitor device 262 in parallel circuit with an impedance 264 (e.g., a 10 ohm resistor) and coupled to a controller 268 so that warnings, trips, or appropriate ground switching actions,. Although the description herein generally refers to discharge event, it will be appreciated that the energy in the discharge event may be proportional to leakage voltage. In accordance with aspects of the present invention, in the event the discharge event exceeds certain thresholds, a warning message will be sent.

As further shown in FIG. 8, electrical propulsion system 210 further comprises a plurality of contactors 210.sub.1-210.sub.2 that may be individually set either in an electrically closed condition or in electrically open condition. When in the closed condition, a respective contactor is electrically coupled in circuit series with a respective one of the traction motors 28 to receive voltage from the DC bus.

In accordance with further aspects of the present invention, prior to switching to the second ground connection 274, one can perform a test sequence that allows determining which particular traction motor may be experiencing the incipient ground fault condition. For example, one may initially set contactor 210.sub.1 (or any of the other contactors 210.sub.2 in the propulsion system) from the closed condition to an open condition. The inventors of the present invention have recognized that a characteristic in the monitored transient signal response can be indicative of the presence of the incipient ground fault in connection with the respective traction motor associated with that contactor.

It is noted that in reconnecting the ground reference point in any electrical system can have various effects. One is to shift the voltage potential relative to ground at various locations in the circuit. This can advantageously change the working voltage to which the insulation system(s) may be subjected. For example, a reduction in this working voltage can effectively reduce the electrical insulation needs and thus reduce the leakage current that could develop at any insulation degradation points. This reduction in current in turn can beneficially reduce the rate of damage accumulation at the fault point. This reduced rate of damage may allow for additional time to pass before reaching equipment functional failure. Also, this additional time may allow for any moisture related leakage paths to dry out.

In general, any electrical system with a fixed circuit ground location, and a ground fault detection technique limited to measuring leakage current at that fixed location, will lack the ability to detect grounds in the circuit which are at a relatively low potential with respect to the system ground point. For example, for the alternator neutral ground connection shown any insulation failures that occur at a circuit location electrically adjacent to (or at) the alternator neutral node 224 will not be detectable if one were to use the ground detection techniques of the prior art that rely on a fixed ground location. One advantageous aspect of the present invention is that having the ability to selectively switch the ground connection point to one or more electrically different locations essentially allows insulation failure detection anywhere in the circuit. That is, blind spots for detecting a ground fault can be essentially eliminated. For example, in one embodiment of the present invention, one may from time-to-time (even in the absence of any excessive current leakage indication) switch from the first ground connection 252 to the second ground connection 274. If no leakage current is detected at the second ground connection, then this would indicate no incipient ground faults anywhere in the circuit. If, however, one were to detect excessive leakage current at the second ground connection, then this would indicate an incipient ground fault electrically proximate to the neutral node. This switching action may be performed as desired for a given application (e.g., once weekly, every other week, or the like).

We will now describe another example of ground fault location determination based on leakage current effects that may develop at the different ground connections for the circuit. For example, assuming detection of leakage current occurs at the first ground connection and further assuming that upon switching to the second ground connection 274, leakage current also occurs at the second ground connection, then this would be indicative of an incipient ground fault electrically proximate to the positive rail of the DC bus. Thus, analysis of the monitored leakage current may be performed to obtain diagnostics information regarding the incipient ground fault, such as determining a likely location of the ground fault in the circuit. In this invention we are extending the concept of leakage current but measuring effects of discharge events.

It should be appreciated that if the voltage potential at a given circuit location is reduced, then the working voltage at other circuit locations may be affected, e.g., may result in higher working voltage at these other circuit locations. This higher voltage in turn can increase the insulation stress for these other locations of the circuit. Accordingly, these effects should be considered in the connection point switching strategy. For example, one way of addressing these effects may be performing a voltage deration (e.g., reduced generator excitation) or reduced periods of operation could be called for while operating at these higher potentials. For example, for the circuit embodiment illustrated in FIG. 1, when the ground connection is switched from the neutral node 12 to the negative DC bus, the voltage relative to ground can increase significantly at the neutral node and also at the traction motor armature. For this embodiment, the voltage drop across the motor field is relatively low compared to the drop across the armature 28. In general, most circuit architectures would favor a primary ground connection point to be used during healthy circuit conditions. A secondary ground connection point may be switched to for diagnostic purposes (e.g., increasing the voltage at various circuit locations).

As noted above, diagnostics information can be obtained from effects that may occur in the leakage current as the system ground connection point is switched from one point to another. Generally, if leakage current decreases (for a given system voltage level) then the ground fault itself is likely at a location which experiences a potential reduction as a result of the connection switch. In the embodiment of FIG. 8, the contactors and associated switchgear are shown in a “motoring” configuration.

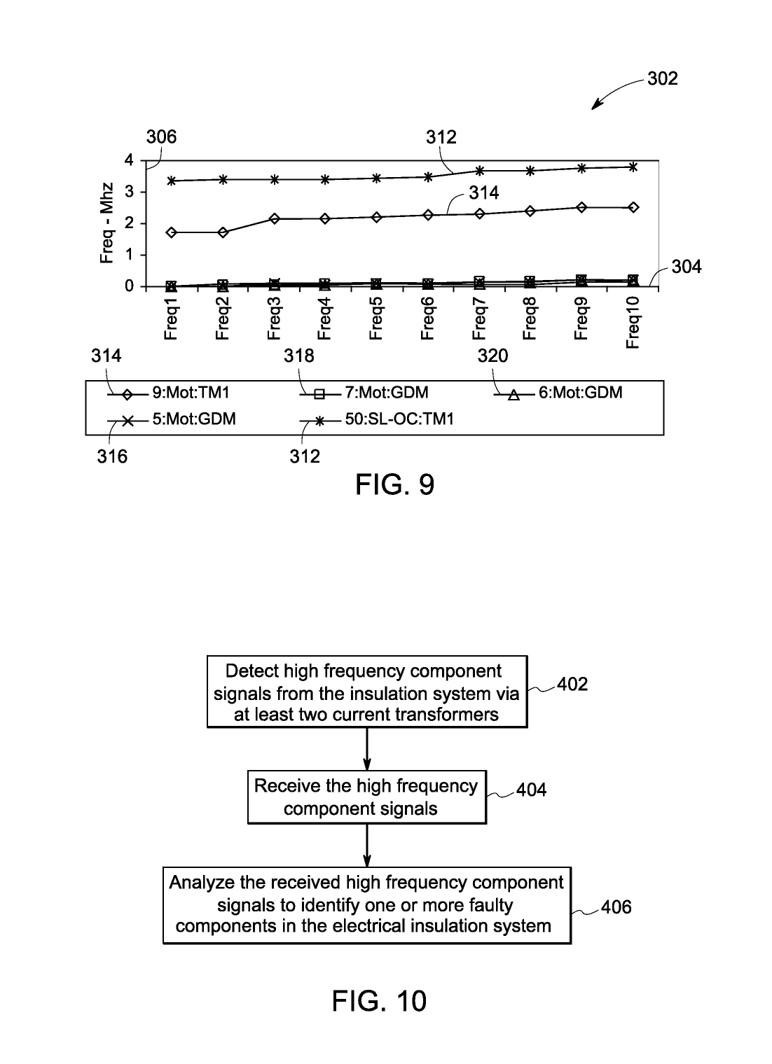

FIG. 9 is a graphical illustration 302 of experiments performed via system 210 in FIG. 8 including HFCTs at various locations in the circuit. As discussed earlier in FIGS. 4-7, the top 10 frequencies in the frequency spectrum obtained by the HFCTs 212, 214 were plotted each configuration after a FFT analysis of the acquired signals. X-axis 304 represents the top 10 frequencies, while Y-axis 306 represents frequency in MHz. As illustrated herein, the configuration wherein one of the HFCTs which initially triggers the measurement, say 212, was electrically coupled to the faulty traction motor 234 at a 20 mV trigger setting and the other HFCT 214 was electrically coupled to the ground detection module (GDM), output high frequencies of the order >1 MHz, as referenced by numerals 312 and 314. The other configurations output low frequencies, as represented by numerals 316, 318, and 320. It was thus inferred that one of the HFCTs has to be electrically coupled at a trigger voltage of 20 mV in each of the traction motors 234, 235, and the second HFCT should be connected to the GDM 226.

FIG. 10 is a flow chart representing steps in an exemplary method for failure detection in an electrical insulation system. The method includes detecting high frequency component signals from the insulation system via at least two current transformers in step 402. The high frequency component signals are received in step 404. The received high frequency component signals are analyzed to identify one or more faulty components in the electrical insulation system in step 406. In one embodiment, a fast fourier transform of the received high frequency component signals is performed. In another embodiment, one or more top frequencies are identified in a frequency spectrum of the signals. In yet another embodiment, a peak-to-peak amplitude of the high frequency component signals is determined In another embodiment, an operator is alerted in the event of a faulty component being detected.

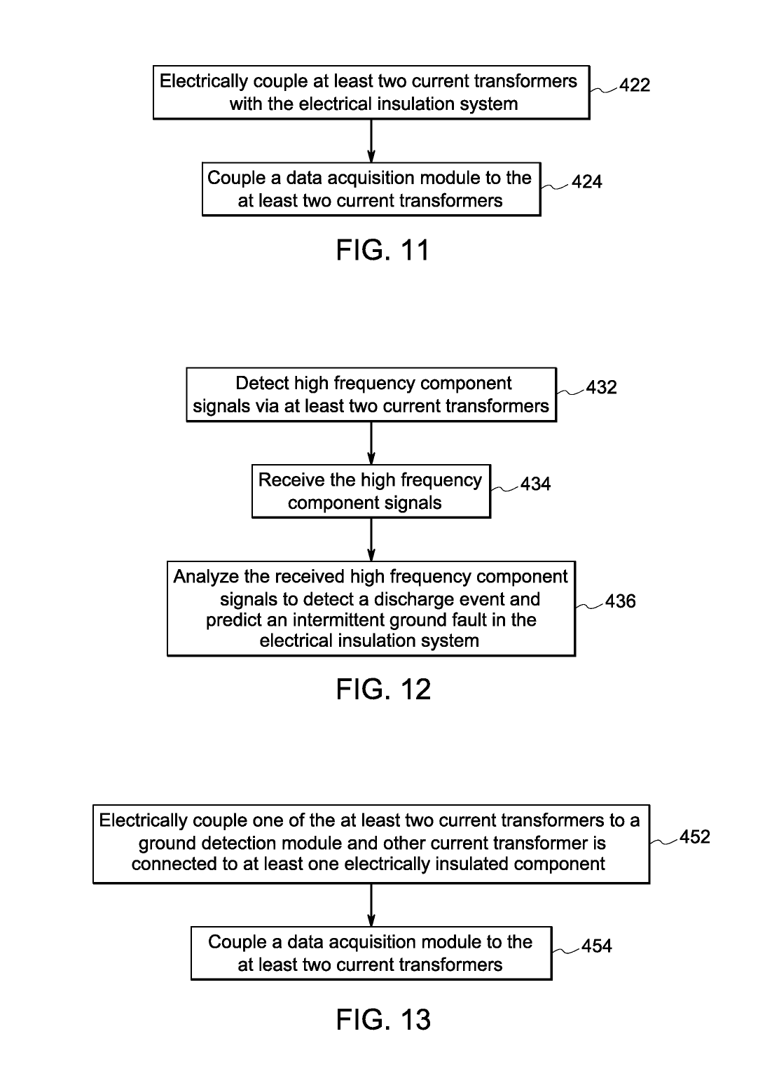

FIG. 11 is a flow chart representing steps in an exemplary method for setting up a prognostics/diagnostics system in an electrical insulation system. The method includes electrically coupling at least two current transformers with the electrical insulation system in step 422, wherein the current transformers are designed to detect high frequency component signals from the insulation system. A data acquisition module is coupled to the at least two current transformers in step 424, wherein the data acquisition module receives and analyzes the high frequency component signals to identify one or more faulty components in the electrical insulation system. In one embodiment, at least two current transformers are clamped to meggering cables connected to the electrical insulation system.

FIG. 12 is a flow chart representing steps in an exemplary method for intermittent ground fault detection in an electrical insulation system. The method includes detecting high frequency component signals via at least two current transformers in step 432, wherein at least one of the two current transformers is electrically coupled to a ground detection module and the other is connected to at least one electrically insulated component. The high frequency component signals are received in step 434. In a particular embodiment, the high frequency component signals are received based upon a triggering of the at least one current transformer clamped to the electrically insulated component. The received high frequency component signals are analyzed to detect discharge event and predict an intermittent ground fault in the electrical insulation system in step 436. In one embodiment, a fast fourier transform of the received high frequency component signals is performed. In another embodiment, one or more top frequencies are identified in a frequency spectrum of the signals. In yet another embodiment, a peak-to-peak amplitude of the high frequency component signals is determined In a particular embodiment, an operator is alerted in the event of a faulty component being detected. In another embodiment, a fault condition is identified if a maximum peak-to-peak amplitude is greater than a threshold amplitude value and a top frequency is greater than a threshold frequency value.

FIG. 13 is a flow chart representing steps in an exemplary method for setting up a prognostics/diagnostics system for intermittent ground fault detection in an electrical insulation system. The method includes electrically coupling one of the at least two current transformers to a ground detection module and other current transformer to at least one electrically insulated component in step 452, wherein the current transformers designed to detect high frequency component signals from the insulation system. A data acquisition module is coupled to the at least two current transformers instep 454. The data acquisition module receives and analyzes the high frequency component signals based upon meggered data to identify one or more faulty components in the electrical insulation system.

The various embodiments of a prognostic/diagnostics system and method for electric wire insulation failures described above thus provide a way to achieve a low cost and efficient means to identify the faulty component/s. These techniques and systems also allow for diagnostics when the components are connected or in operation thus minimizing maintenance and repair time and costs. Specifically, in an embodiment, the data acquisition module is configured to identify faulty condition during operation of the electrical insulation system.

Another embodiment relates to a method for failure detection in an electrical insulation system. The method comprises detecting high frequency component signals from the insulation system via at least two current transformers, receiving the high frequency component signals, and analyzing the received high frequency component signals to identify one or more faulty components in the electrical insulation system. In another embodiment, the step of analyzing comprises: determining a frequency threshold for a top frequency in a frequency spectrum of the signals; determining an amplitude threshold value for a maximum peak-to-peak amplitude of the high frequency component signals; and identifying a fault condition if the maximum peak-to-peak amplitude of the high frequency component signals is greater than the amplitude threshold and if the top frequency is greater than the frequency threshold.

Another embodiment relates to a method for setting up a prognostics/diagnostics system for failure detection in an electrical insulation system. The method comprises electrically coupling at least two current transformers with the electrical insulation system (e.g., coupling may include clamping the at least two current transformers to meggering cables connected to the electrical insulation system). The current transformers are designed to detect high frequency component signals from the insulation system. The method further comprises electrically coupling a data acquisition module to the at least two current transformers. The data acquisition module is configured to receive and analyze the high frequency component signals to identify one or more faulty components in the electrical insulation system.

Another embodiment relates to a method for setting up a prognostics/diagnostics system for intermittent ground fault detection in an electrical insulation system. The method comprises electrically coupling one of the at least two current transformers to a ground detection module and the other current transformer to at least one electrically insulated component. The current transformers are designed to detect high frequency component signals from the insulation system. The method further comprises coupling a data acquisition module to the at least two current transformers. The data acquisition module is configured to receive and analyze the high frequency component signals to identify one or more faulty components in the electrical insulation system.

Another embodiment relates to a passive system for detecting insulation failure in an electrical system. The passive system comprises at least two current transformers clamped and designed to passively sense one or more fault signals. The passive system further comprises a data acquisition module comprising a plurality of software models that are configured to continuously analyze and produce a defect report or warning in real time when a fault signal is detected. The passive system may be configured for intermittent ground fault detection in an electrical insulation system. The at least two current transformers may be clamped and configured to passively listen for fault signals when a megger test is being performed.

Of course, it is to be understood that not necessarily all such objects or advantages described above may be achieved in accordance with any particular embodiment. Thus, for example, those skilled in the art will recognize that the systems and techniques described herein may be embodied or carried out in a manner that achieves or optimizes one advantage or group of advantages as taught herein without necessarily achieving other objects or advantages as may be taught or suggested herein.

Furthermore, the skilled artisan will recognize the interchangeability of various features from different embodiments. Similarly, the various features described, as well as other known equivalents for each feature, can be mixed and matched by one of ordinary skill in this art to construct additional systems and techniques in accordance with principles of this disclosure.

Although the systems herein have been disclosed in the context of certain preferred embodiments and examples, it will be understood by those skilled in the art that the invention extends beyond the specifically disclosed embodiments to other alternative embodiments and/or uses of the systems and techniques herein and obvious modifications and equivalents thereof Thus, it is intended that the scope of the invention disclosed should not be limited by the particular disclosed embodiments described above, but should be determined only by a fair reading of the claims that follow.

While only certain features of the invention have been illustrated and described herein, many modifications and changes will occur to those skilled in the art. It is, therefore, to be understood that the appended claims are intended to cover all such modifications and changes as fall within the true spirit of the invention.

1. A diagnostic/prognostics system for failure detection in an electrical insulation system comprising:
at least two current transformers designed to detect high frequency component signals from the insulation system; and
a data acquisition module coupled to the at least two current transformers, the data acquisition module configured to:
receive the high frequency component signals; and
analyze the received high frequency component signals to identify one or more faulty components in the electrical insulation system.

2. The system of claim 1, wherein said high frequency component signals comprise a frequency between about 10 kHz to about 200 MHz.

3. The system of claim 1, wherein said data acquisition module comprises one or more software models to analyze the received high frequency component signals, wherein said software models identify a faulty condition based on comparison with a threshold value of maximum peak-to-peak amplitude and a threshold value of frequency.

4. The system of claim 1, wherein said electrical insulation system comprises a traction motor insulation system.

5. The system of claim 1, wherein said components comprise an armature or field coil.

6. The system of claim 1, wherein said at least two current transformers are clamped to meggering cables coupled to the electrical insulation system to detect the high frequency component signals.

7. The system of claim 1, wherein:
at least one of the two current transformers is clamped to a ground detection module and the other is clamped to at least one electrically insulated component; and
the data acquisition module is configured to analyze the received high frequency component signals to detect leakage current and detect/predict an intermittent ground fault in the electrical insulation system.

8. The system of claim 7, wherein said one of the at least two current transformers is triggered prior to detecting the high frequency component signals, and wherein said one of the at least two current transformers is triggered based upon comparison of the high frequency signals with a threshold maximum peak-to-peak amplitude.

9. A method for failure detection in an electrical insulation system comprising:
detecting high frequency component signals from the insulation system via at least two current transformers;
receiving the high frequency component signals; and
analyzing the received high frequency component signals to identify one or more faulty components in the electrical insulation system.

10. The method of claim 9, wherein said analyzing comprises performing a fast fourier transform of the received high frequency component signals.

11. The method of claim 9, wherein said analyzing comprises identifying one or more top frequencies in a frequency spectrum of the signals.

12. The method of claim 11, wherein said analyzing further comprises identifying a fault condition if a maximum peak-to-peak amplitude of the high frequency component signals is greater than an amplitude threshold and a top frequency of the one or more top frequencies is greater than a frequency threshold.

13. The method of claim 9, wherein said analyzing comprises determining a peak-to-peak amplitude of the high frequency component signals.

14. The method of claim 9, further comprising alerting an operator in event of a faulty component.

15. The method of claim 9, wherein:
at least one of the two current transformers is electrically coupled to a ground detection module and the other is connected to at least one electrically insulated component; and
analyzing the received high frequency component signals comprises analyzing the received high frequency component signals to detect a discharge event and predict an intermittent ground fault in the electrical insulation system.

16. The method of claim 15, wherein said analyzing comprises performing a fast fourier transform of the received high frequency component signals.

17. The method of claim 15, further comprising alerting an operator in event of a faulty component.

18. The method of claim 15, wherein said analyzing comprises identifying one or more top frequencies in a frequency spectrum of the high frequency component signals, determining a maximum peak-to-peak amplitude of the high frequency component signals, and identifying a fault condition if the maximum peak-to-peak amplitude is greater than a threshold amplitude value and if a top frequency of the one or more top frequencies is greater than a threshold frequency value.

19. The method of claim 15, wherein said receiving the high frequency component signals comprises receiving the signals based upon triggering of the at least one current transformer clamped to the electrically insulated component.

20. A passive system for detecting insulation failure in an electrical system comprising:
at least two current transformers clamped and designed to passively sense one or more fault signals; and
a data acquisition module comprising a plurality of software models that are configured to continuously analyze and produce a defect report or warning in real time when a fault signal is detected.
